(19) United States
(12) Patent Application Publication
(10) Pub. No.: US 2026/0305381 A1
(43) Pub. Date: Oct. 1, 2026

(54) POWER SEMICONDUCTOR PACKAGE INCLUDING A MOLDED BODY WITH PROTRUSION AND METHOD FOR FABRICATING THE SAME

(71) Applicant: Infineon Technologies AG, Neubiberg (DE)

(72) Inventors: Arivindran Navaretnasinggam, Seremban (MY); Sanjay Kumar Murugan, Taman Mas Merah Jaya (MY); Muhammad Safie Rosli, Taman Vista Belimbing (MY); Dominic Carlos Anonuevo, Batu Berendam (MY)

(21) Appl. No.: 19/629,493

(22) Filed: Mar. 26, 2026

(30) Foreign Application Priority Data
Mar. 27, 2025 (DE) 102025111973.2

(51) Int. Cl. H10W 70/40; H10W 70/04; H10W 74/01; H10W 74/10; H10W 90/00

(52) U.S. Cl. CPC H10W 70/429; H10W 70/048; H10W 74/01; H10W 74/114; H10W 90/766

(57) ABSTRACT

A power semiconductor package includes: a leadframe having a plurality of first leads; a power semiconductor die electrically connected to the leadframe; and a molded body encapsulating the power semiconductor die. The molded body includes a first side, an opposite second side, and lateral sides connecting the first and second sides. The first leads protrude from a first one of the lateral sides of the molded body. The first leads include end faces facing away from the first one of the lateral sides of the molded body and lateral faces extending from the first one of the lateral sides to the respective end face. At least two opposite lateral faces of each of the first leads are covered by protrusions of the molded body.

### TECHNICAL FIELD

The present disclosure relates to a power semiconductor package, in particular to a power semiconductor package comprising a molded body with protrusions, as well as to a method for fabricating such a power semiconductor package.

### BACKGROUND

A power semiconductor package may comprise a leadframe, a power semiconductor die coupled to the leadframe and a molded body encapsulating the power semiconductor die. The leadframe may comprise leads, which are exposed from the molded body and which are configured to act as external contacts of the power semiconductor die. Fabricating the molded body may comprise arranging the leadframe with the power semiconductor die in a mold cavity, such that the leads extend through openings in a side wall of the mold cavity and molding over the power semiconductor die. Fabrication of the power semiconductor package may further comprise cutting through the leadframe. This cutting may comprise cutting through the leads, for example in order to fabricate leads with a well-defined length and/or a well-defined end face facing away from the power semiconductor package. The cutting process may also comprise cutting through a portion of the molded body, for example through a portion of the molded body abutting the leads. The molded body may for example comprise fringes or mold flash at the leads due to a slight difference in size between the openings in the side wall of the mold cavity and the leads. Cutting through these undefined fringes may leave residues of mold material on the leads, which may for example impair the electrical characteristics and/or the solderability of the leads. Improved power semiconductor packages as well as improved methods for fabricating a power semiconductor package may help with solving these and other problems.

### SUMMARY

Various aspects pertain to a power semiconductor package, comprising: a leadframe comprising a plurality of first leads, a power semiconductor die electrically connected to the leadframe, and a molded body encapsulating the power semiconductor die, the molded body comprising a first side, an opposite second side and lateral sides connecting the first and second sides, wherein the first leads protrude from a first one of the lateral sides of the molded body, wherein the first leads comprise end faces facing away from the first one of the lateral sides of the molded body and lateral faces extending from the first one of the lateral sides to the respective end face, and wherein at least two opposite lateral faces of each of the first leads are covered by protrusions of the molded body.

Various aspects pertain to a method for fabricating power semiconductor package, the method comprising: providing a leadframe comprising a plurality of first leads, electrically connecting a power semiconductor die to the leadframe, and molding over the power semiconductor die, thereby forming a molded body, the molded body comprising a first side, an opposite second side and lateral sides connecting the first and second sides, wherein the first leads protrude from a first one of the lateral sides of the molded body, wherein the first leads comprise end faces facing away from the first one of the lateral sides of the molded body and lateral faces extending from the first one of the lateral sides to the respective end face, and wherein at least two opposite lateral faces of each of the first leads are covered by protrusions of the molded body.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B schematically illustrate a power semiconductor package comprising first leads exposed from a molded body, wherein the molded body comprises protrusion that cover lateral faces of the first leads. FIG. 1A illustrates a plan view of the power semiconductor package and FIG. 1B illustrates a sectional view.

FIG. 2 shows a detail view of a first lead and corresponding protrusions of the molded body of the power semiconductor package illustrated in FIGS. 1A and 1B, according to an example.

FIG. 3 shows a detail view of a first lead and the corresponding protrusions, according to another example. In particular, in the example illustrated in FIG. 3, each of the protrusions comprises a first portion with a first thickness and a second portion with a different second thickness.

FIG. 4 shows a perspective view of a first lead and the corresponding protrusions, according to a further example. In particular, in the example illustrated in FIG. 4, the protrusions are tapered.

FIG. 5 shows a plan view of a further power semiconductor package comprising the first leads and the associated protrusions of the molded body and also second leads which do not have any associated protrusions of the molded body.

FIGS. 6A-6F illustrate the power semiconductor package of FIG. 5 in various stages of fabrication, according to an exemplary method for fabricating a power semiconductor package.

FIG. 7 is a flow chart of an exemplary method for fabricating a power semiconductor package.

### DETAILED DESCRIPTION

In the following detailed description, known structures and elements are shown in schematic form in order to facilitate describing one or more aspects of the disclosure. In this regard, directional terminology, such as "top", "bottom", "left", "right", "upper", "lower" etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms "include", "have", "with" or other variants thereof are used in either the detailed description or the claims, such terms are intended to be inclusive in a manner similar to the term "comprise". The terms "coupled" and "connected", along with derivatives thereof may be used. It should be understood that these terms may be used to indicate that two elements cooperate or interact with each other regardless whether they are in direct physical or electrical contact, or they are not in direct contact with each other; intervening elements or layers may be provided between the "bonded", "attached", or "connected" elements. However, it is also possible that the "bonded", "attached", or "connected" elements are in direct contact with each other. Also, the term "exemplary" is merely meant as an example, rather than the best or optimal.

The examples of a power semiconductor package described below may use various types of semiconductor dies, among them power MOS transistors, power Schottky diodes, JFETs (Junction Gate Field Effect Transistors), power bipolar transistors, etc. The examples may also use semiconductor dies comprising MOS transistor structures or vertical transistor structures like, for example, IGBT (Insulated Gate Bipolar Transistor) structures or, in general, transistor structures in which at least one electrical contact pad is arranged on a first side of the semiconductor die and at least one other electrical contact pad is arranged on a second side of the semiconductor die, opposite to the first side.

The power semiconductor die(s) may be manufactured from specific semiconductor material, for example Si, SiC, SiGe, GaAs, GaN, or from any other suitable semiconductor material, and, furthermore, may contain one or more of inorganic and organic materials that are not semiconductors, such as for example insulators, plastics or metals.

An efficient power semiconductor package and an efficient method for fabricating a power semiconductor package may for example reduce material consumption, ohmic losses, chemical waste, etc. and may thus enable energy and/or resource savings. Improved power semiconductor packages and improved methods for fabricating a power semiconductor package, as specified in this description, may thus at least indirectly contribute to green technology solutions, i.e. climate-friendly solutions providing a mitigation of energy and/or resource use.

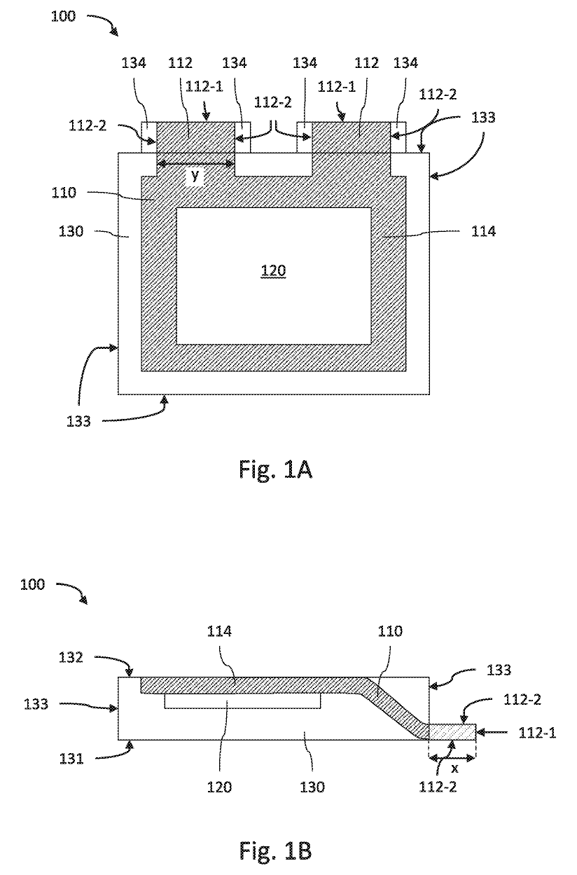

FIGS. 1A and 1B schematically show a plan view (FIG. 1A) and a sectional view (FIG. 1B) of a power semiconductor package 100 comprising a leadframe 110, a power semiconductor die 120 and a molded body 130. Note that the molded body 130 is transparent in FIGS. 1A and 1B in order to illustrate the interior of the power semiconductor package 100. The power semiconductor package 100 may comprise further components not illustrated in FIGS. 1A and 1B for the sake of clarity.

The power semiconductor package 100 may be a discrete package comprising a single power semiconductor die 120 or the power semiconductor package 100 may comprise a plurality of power semiconductor dies 120. In the latter case, the power semiconductor dies 120 may all be the same type of die or different types of dies. Furthermore, the power semiconductor package 100 may comprise any suitable electrical circuit realized using the power semiconductor die(s) 120, for example a single switch, a half bridge circuit, a full bridge circuit, a converter circuit, an inverter circuit, etc.

The power semiconductor package 100 may be configured to operate with a high voltage, e.g. a voltage of 100V or more, or 500V or more, or 1.2kV or more, or even 2kV or more. Furthermore, the power semiconductor package 100 may be configured to operate with a strong electrical current, for example a current of 1A or more, or 10A or more, or even 100A or more.

The power semiconductor package 100 may be configured for use in any suitable application, for example automotive applications, industrial applications or household applications. According to a specific example, the power semiconductor package 100 is configured for use in the main inverter of an electric engine of an electric vehicle.

The leadframe 110 comprises a plurality of first leads 112. The leadframe 110 may also comprise a die pad 114, wherein the power semiconductor die 120 may be arranged on the die pad 114. According to an example, the die pad 114 and the first leads 112 are a monolithic part, compare FIG. 1A. According to another example, the die pad 114 and only some or even only one of the first leads 112 are a monolithic part. According to yet another example, the die pad 114 and none of the first leads 112 form a monolithic part.

The leadframe 110 may comprise any suitable number of first leads 112. For example, the leadframe 110 may comprise two, three, four, etc. first leads 112. According to an example, the power semiconductor package 100 may comprise one or more further leads, which may or may not be part of the leadframe 110. Instead, the further leads may for example be part of a further leadframe or a clip, which may for example be arranged over or below the leadframe 110.

The leadframe 110 may comprise or consist of any suitable metal or metal alloy. For example, the leadframe 110 may comprise or consist of Al or Cu. According to an example, the leadframe 110 is plated, for example with a plating comprising or consisting of one or more of Ni and Sn. The plating may for example cover only a portion of the leadframe, e.g. the portion that is exposed from the molded body 130, or the plating may cover the leadframe 110 completely. According to another example, the leadframe 110 is not covered by a plating.

The power semiconductor die 120 is electrically connected to the leadframe 110, e.g. to the die pad 114. The power semiconductor die 120 may for example comprise a first power electrode on a first side facing away from the leadframe 110 and a second power electrode on an opposite second side, wherein the second side faces the leadframe 110, in particular the die pad 114. The second power electrode may e.g. be connected to the die pad 114 via a solder joint, a sintered joint or a joint comprising conductive glue. The first power electrode may e.g. be a source electrode or an emitter electrode and the second power electrode may e.g. be a drain electrode or a collector electrode. According to another example, it is the other way around. The power semiconductor die 120 may further comprise a gate electrode, arranged e.g. on the first side.

According to an example, it is also possible that the power semiconductor die 120 is a lateral transistor device, wherein both power electrodes are arranged on the same side, laterally next to each other.

In the case that one or more of the first leads 112 and the die pad 114 are no monolithic part, a power electrode, in particular the first power electrode, may be connected to this first lead 112 or to these first leads 112 using a connector like a bond wire, a ribbon or a contact clip.

The molded body 130 encapsulates the power semiconductor die 120. The molded body 130 may comprise or consist of any suitable mold material. The molded body 130 may be fabricated using any suitable molding technique, for example compression molding, injection molding or transfer molding. According to an example, the molded body 130 comprises inorganic filler particles configured to reduce the thermal resistance of the molded body 130.

The molded body 130 comprises a first side 131, an opposite second side 132 and lateral sides 133 connecting the first and second sides 131, 132. The first leads 112 protrude from a first one of the lateral sides 133 of the molded body 130. According to an example, no first leads 112 are arranged at any of the other lateral sides 133.

The first leads 112 may, for example, protrude from the first one of the lateral sides 133 by a protrusion length x in the range of about 0.2mm to about 1.2mm. The lower limit of this range may also be about 0.3mm, or about 0.4mm, or about 0.5mm and the upper limit may also be about 1mm, or about 0.8mm, or about 0.6mm. The first leads 112 may have any suitable width y measured perpendicular to the protrusion length x. For example, the width y may be in the range of about 0.5mm to about 3mm. The lower limit of this range may also be about 0.7mm, or about 0.9mm and the upper limit may also be about 2mm, or about 1.5mm, or about 1.2mm.

The leadframe 110 may have any suitable thickness, the thickness being measured perpendicular to the protrusion length x and the width y. The thickness of the leadframe 110, in particular the thickness of the first leads 112, may for example be in the range of about 0.3mm to about 1mm. The lower limit of this range may also be about 0.4mm or about 0.5mm and the upper limit may also be about 0.8mm or about 0.6mm.

The die pad 114 may be exposed from the molded body 130, for example in order to be coupled to a heatsink. As shown in FIG. 1B, the die pad 114 may e.g. be exposed from the second side 132 of the molded body 130. However, it is also possible that the die pad 114 is exposed from the first side 131 or that the die pad 114 is not exposed from the molded body 130.

The first leads 112 comprise end faces 112-1 facing away from the first one of the lateral sides 133 of the molded body 130. The first leads 112 furthermore comprise lateral faces 112-2 extending from the first one of the lateral sides 133 to the end face 112-1. The end faces 112-1 may essentially be perpendicular to the lateral faces 112-2. The end faces 112-1 may essentially be perpendicular to the first and second sides 131, 132 of the molded body 130. Each first lead 112 may comprise four lateral faces 112-2, wherein two of the lateral faces 112-2 may essentially be perpendicular to the first and second sides 131, 132 of the molded body 130 and the two other lateral faces 112-2 may essentially be parallel to the first and second sides 131, 132. As shown in FIG. 1B, one of the lateral faces 112-2 may be coplanar with the first side 131. However, this does not necessarily have to be the case.

As shown in FIG. 1A, at least two opposite lateral faces 112-2 of each of the first leads 112 are covered by protrusions 134 of the molded body 130 (in FIG. 1A, the two laterals faces 112-2 that are perpendicular to the drawing plane are covered by the protrusions 134). The protrusions 134 protrude from the first one of the lateral sides 133 of the molded body 130 and are in direct contact with the two respective lateral faces 112-2 of each of the first leads 112. According to the example shown in FIGS. 1A and 1B, the protrusions 134 completely cover the two respective lateral faces 112-2 of each of the first leads 112. The remaining two lateral faces 112-2 (i.e. the two lateral faces 112-2 that are parallel to the drawing plane in FIG. 1A) may be free of the protrusions 134.

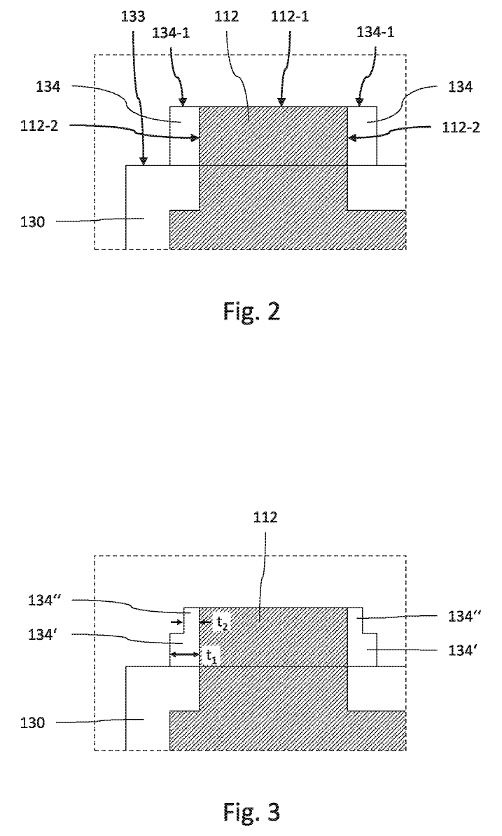

FIG. 2 shows a detail of the power semiconductor package 100, in particular the first lead 112 and protrusions 134 as shown in FIGS. 1A and 1B.

According to an example, the end faces 112-1 of the first leads 112 are cut surfaces. The cut surfaces may for example be fabricated using a suitable punch cutting process or stamping process. The protrusions 134 may also comprise end faces 134-1 facing away from the first one of the lateral sides 133 of the molded body 130. According to an example, the end faces 134-1 of the protrusions 134 may be cut surfaces. The cut surfaces of the protrusions may in particular be fabricated with the same process as the cut surfaces of the first leads 112.

As shown in FIG. 2, the end face 112-1 of each first lead 112 and the end faces 134-1 of the respective protrusions 134 may be coplanar. This may in particular be the case if both end faces 112-1, 134-1 are fabricated with the same cutting process.

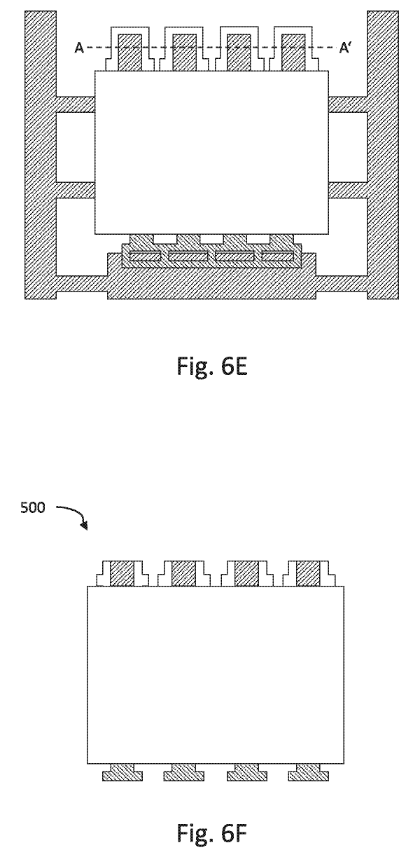

The protrusions 134 may be fabricated using a molding tool with suitably dimensioned openings for the first leads 112, that is with openings that are slightly wider than the first leads 112, such that liquid mold material can flow along and cover the two opposite lateral faces 112-2 of each first lead 112. This is explained in greater detail with respect to FIGS. 6A-6F.

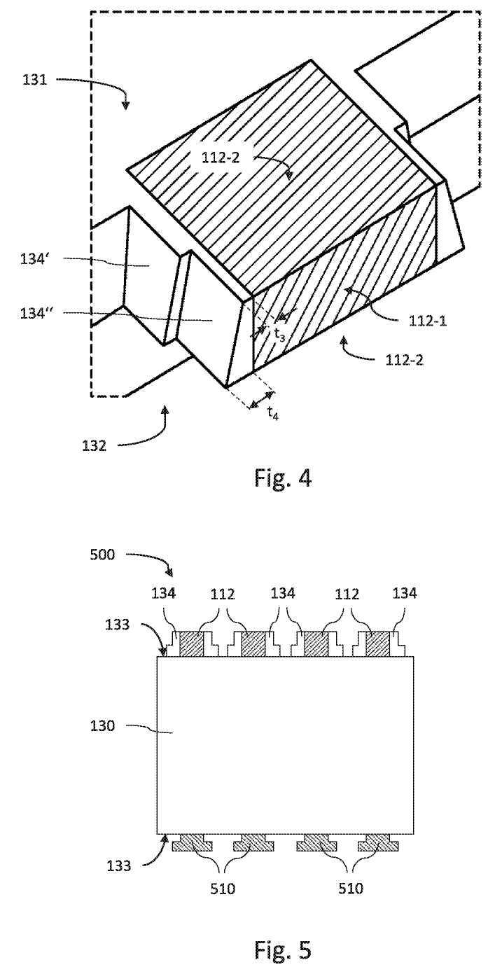

FIG. 3 shows a detail view of a first lead 112 and protrusions 134 according to another example. The power semiconductor package 100 may comprise the protrusions 134 as shown in FIG. 3 instead of the protrusions shown in FIG. 2.

As shown in FIG. 3, a contour of the protrusions 134 may comprise an offset as viewed from above the first side 131 of the molded body 130. In other words, the protrusions 134 each comprise a first portion 134' arranged closer to the first one of the lateral sides 133 and a second portion 134'' arranged further away from the first one of the lateral sides 133. The first portion 134' has a thickness t₁ that is greater than a thickness t₂ of the second portion 134''.

The thickness t₁ may have any suitable value and may for example be in the range of about 0.08mm to about 0.5mm. The lower limit of this range may also be about 0.1mm or about 0.12mm and the upper limit may also be about 0.3mm or about 0.2mm. The thickness t₂ may likewise have any suitable value and may for example be in the range of about 0.03mm to about 0.3mm. The lower limit of this range may also be about 0.05mm or about 0.06mm and the upper limit may also be about 0.2mm or about 0.15mm or about 0.1mm.

In the example shown in FIG. 3, the offset between the first and second portions 134', 134'' essentially has the shape of a step. However, it is for example also possible that the offset comprises a gradual transition from the first thickness t₁ to the second thickness t₂ or that the offset comprises several steps.

The offset may for example be arranged about halfway between the first one of the lateral sides 133 and the end face 112-1. In other words, a length of the first portion 134' may be about equal to a length of the second portion 134''. However, it is also possible that a ratio between the lengths of the first and second portions 134', 134'' has any other suitable value, for example a value in the range of about 1:2 to about 2:1, for example about 1:1.5 or about 1.5:1.

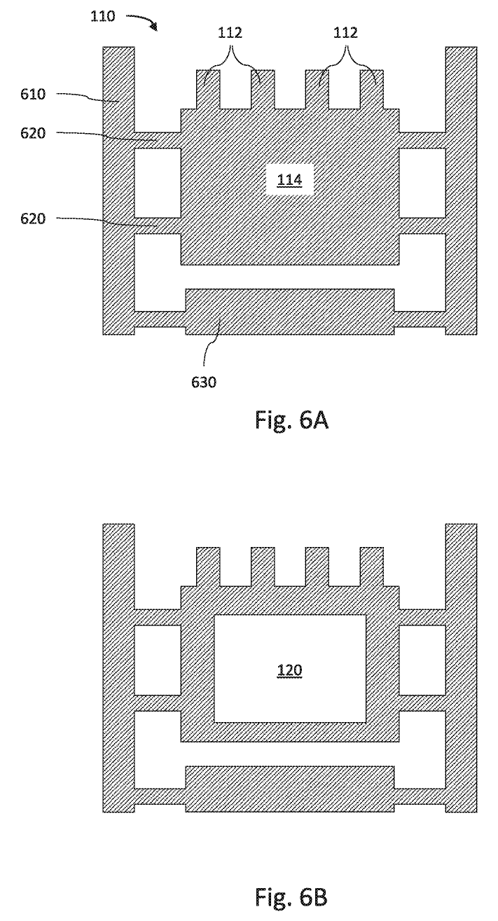

FIG. 4 shows a perspective view of the first lead 112 and the protrusions 134, according to a further example.

In the example shown in FIG. 4, the protrusions 134 are tapered such that a thinner side or thinner end is arranged at the first side 131 of the molded body 130 and a thicker side or thicker end is arranged at the second side 132 of the molded body 130.

The thinner end of the second portion 134'' may for example have a thickness t₃ in the range of about 0.03mm to about 0.06mm, for example about 0.04mm or about 0.05mm. The thicker end of the second portion 134'' may for example have a thickness t₄ in the range of about 0.1mm to about 0.2mm. The lower limit of this range may also be about 0.12mm or about 0.15mm and the upper limit may also be about 0.18mm. Furthermore, a difference in thickness between the thinner end and the thicker end may for example be in the range of about 0.05mm to about 0.2mm, for example about 0.08mm, or about 0.1mm, or about 0.12mm, or about 0.14mm, or about 0.16mm, or about 0.18mm.

Tapered protrusions 134 as shown in FIG. 4 may e.g. be advantageous during fabrication of the power semiconductor package 100. For example, when the power semiconductor package 100 is removed from a mold cavity after molding, the tapered protrusions 134 may be less likely to stick to the mold tool than protrusions 134 with vertical sidewalls. Additionally or alternatively, the tapered protrusions 134 may be less likely to fray during cutting (the cutting may in particular be performed from the thinner end towards the thicker end).

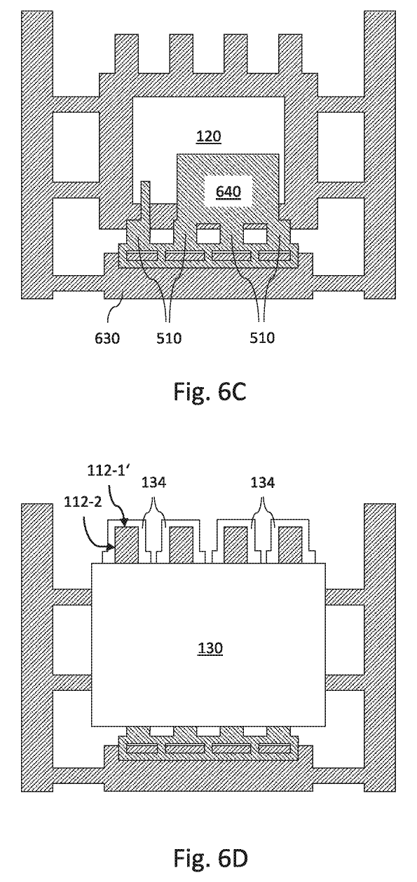

FIG. 5 schematically shows a plan view of a further power semiconductor package 500 which may be similar or identical to the power semiconductor package 100, except for the differences described in the following. Note that in FIG. 5, the molded body 130 is not transparent and therefore the interior of the power semiconductor package 500, in particular the at least one power semiconductor die 120, is not illustrated.

The power semiconductor package 500 may comprise all components described with respect to the power semiconductor package 100. The power semiconductor package 500 further comprises a plurality of second leads 510 exposed from the molded body 130, the second leads 510 being different from the first leads 112.

The second leads 510 may essentially have the same material composition and/or similar shape and/or similar dimensions as the first leads 112. According to an example however, the second leads 510 are not part of the leadframe 110. Instead, during fabrication of the power semiconductor package 500, the second leads 510 may for example be part of a clip or a second leadframe.

The second leads 510 protrude from a second one of the lateral sides 133 of the molded body 130, different from the first one of the lateral sides 133. As shown in FIG. 5, the second one of the lateral sides 133 may for example be opposite the first one of the lateral sides 133. The second leads 510 are not covered by any protrusions of the molded body 130. In other words, all of the lateral faces of the second leads 510 are exposed from the molded body 130.

FIGS. 6A-6F schematically show the power semiconductor package 500 in various stages of fabrication, according to an exemplary method for fabricating a power semiconductor package.

As shown in FIG. 6A, the leadframe 110, comprising the plurality of first leads 112 and the die pad 114, is provided. The die pad 114 and the first leads 112 are coupled to a frame 610 via tie bars 620.

According to an example, the leadframe 110 may optionally comprise a connector portion 630, configured to accept a clip, wherein the second leads 510 of the power semiconductor package 500 are provided using the clip (compare FIG. 6C).

As shown in FIG. 6B, the power semiconductor die 120 is arranged on and electrically connected to the die pad 114. This may comprise a process of soldering, sintering or gluing with conductive glue the power semiconductor die 120 to the die pad 114.

As shown in FIG. 6C, a clip 640 comprising the second leads 510 is arranged over the leadframe 110, in particular over the connector portion 630, and over the power semiconductor die 120. The clip 640 may for example be soldered, sintered or glued with conductive glue to the power semiconductor die 120, in particular to one or more electrodes on the upper side of the power semiconductor die 120. According to an example, the clip 640 may also be soldered, sintered or glued with conductive glue to the connector portion 630.

As shown in FIG. 6D, a molding process is performed in order to encapsulate the power semiconductor die 120 in the molded body 130. This may comprise arranging the leadframe 110 with the power semiconductor die 120 and the clip 640 in a mold cavity, such that the die pad 114 and the power semiconductor die 120 are arranged within the mold cavity and such that the first leads 112 extend through openings in a side wall of the mold cavity. The openings have a slightly larger width than the first leads 112, such that liquid mold material can engulf the lateral faces 112-2 and also preliminary end faces 112-1' of the first leads 112, forming the protrusions 134.

As shown in FIG. 6E, a cutting or stamping process along the line A-A' may be performed in order to remove the preliminary end faces 112-1' and to fabricate the end faces 112-1 of the first leads. According to an example, the clip 640 may be cut in the same cutting process in order to fabricate the second leads 510. However, it is also possible that the second leads 510 are fabricated using a different cutting process.

Note that the protrusions 134 covering the lateral faces 112-2 and the preliminary end faces 112-1' are purposefully fabricated with well-defined thicknesses and widths. Therefore, no fringes or mold flash with undefined lengths and shapes are generated at the position where the first leads 112 extend through the openings of the mold cavity. Cutting through the well-defined protrusions 134 therefore does not result in contamination of the first leads 112 with residues of mold material like cutting through such fringes or mold flash might. The first leads 112 may therefore be particularly suited to fulfill lead-tip inspection (LTI) requirements.

According to an example, fabricating the power semiconductor package 500 may optionally comprise a process of plating over the first leads 112 and possibly also over the second leads 510. The plating may for example comprise or consist of one or more of Ni and Sn. The plating process may for example be performed after the above-mentioned cutting process(es). In this case, the end faces 112-1 of the first leads 112 and possibly also end faces of the second leads 510 are plated. However, it is also possible that the plating process is performed prior to the above-mentioned cutting process(es). In this case, the end faces 112-1 of the first leads 112 and end faces of the second leads 510 are not plated. In either case, the lateral faces 112-2 that are covered by the protrusions 134 are not covered by a plating.

FIG. 6F shows the power semiconductor package 500 after singulation from the frame 610, wherein the singulation process may comprise cutting through the tie bars 620. A similar process as shown with respect to FIGS. 6A-6F may be used to fabricate the power semiconductor package 100.

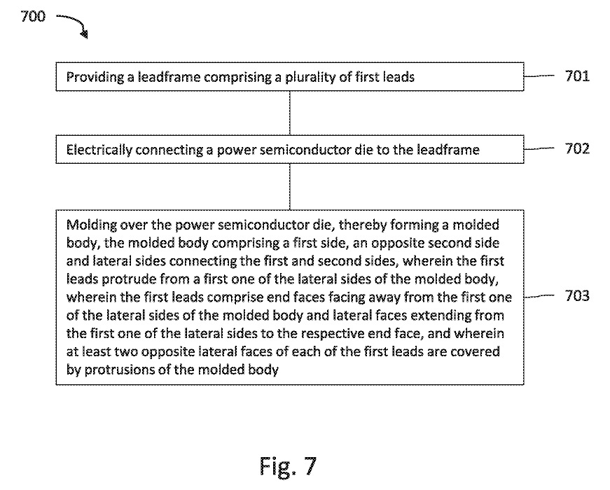

FIG. 7 is a flow chart of an exemplary method 700 for fabricating a power semiconductor package. The method 700 may for example be used to fabricate the power semiconductor packages 100 and 500.

The method 700 comprises at 701 a process of providing a leadframe comprising a plurality of first leads, at 702 a process of electrically connecting a power semiconductor die to the leadframe, and at 703 a process of molding over the power semiconductor die, thereby forming a molded body, the molded body comprising a first side, an opposite second side and lateral sides connecting the first and second sides, wherein the first leads protrude from a first one of the lateral sides of the molded body, wherein the first leads comprise end faces facing away from the first one of the lateral sides of the molded body and lateral faces extending from the first one of the lateral sides to the respective end face, and wherein at least two opposite lateral faces of each of the first leads are covered by protrusions of the molded body.

According to an example of the method 700, the process of molding 703 comprises covering preliminary end faces of the first leads with the molded body. Furthermore, the method 700 may additionally comprise a process of cutting through the first leads, thereby removing the preliminary end faces and fabricating the end faces of the first leads. The cutting may also comprise cutting through the protrusions, thereby forming end faces of the protrusions.

In the following, the power semiconductor package and the method for fabricating a power semiconductor package are further explained using specific examples.

Example 1 is a power semiconductor package, comprising: a leadframe comprising a plurality of first leads, a power semiconductor die electrically connected to the leadframe, and a molded body encapsulating the power semiconductor die, the molded body comprising a first side, an opposite second side and lateral sides connecting the first and second sides, wherein the first leads protrude from a first one of the lateral sides of the molded body, wherein the first leads comprise end faces facing away from the first one of the lateral sides of the molded body and lateral faces extending from the first one of the lateral sides to the respective end face, and wherein at least two opposite lateral faces of each of the first leads are covered by protrusions of the molded body.

Example 2 is the power semiconductor package of example 1, wherein the end faces are cut surfaces, fabricated by punch cutting.

Example 3 is the power semiconductor package of example 1 or 2, wherein the protrusions comprise end faces facing away from the first one of the lateral sides, and wherein the end faces of the protrusions are cut surfaces fabricated by punch cutting.

Example 4 is the power semiconductor package of example 3, wherein the end face of each first lead and the end faces of the respective protrusions are coplanar.

Example 5 is the power semiconductor package of one of the preceding examples, wherein a contour of the protrusions comprises an offset as viewed from above the first side of the molded body, such that a portion of the protrusions closer to the first one of the lateral sides has a greater thickness than a portion further away from the first one of the lateral sides.

Example 6 is the power semiconductor package of example 5, wherein the thickness of the portion further away from the first one of the lateral sides is in the range of 0.03mm to 0.3mm.

Example 7 is the power semiconductor package of one of the preceding examples, wherein the protrusions are tapered such that a thinner side is arranged at the first side of the molded body and a thicker side is arranged at the second side of the molded body.

Example 8 is the power semiconductor package of example 7, wherein a difference in thickness between the thinner side and the thicker side is in the range of 0.05mm to 0.2mm.

Example 9 is the power semiconductor package of one of the preceding examples, further comprising: a plurality of second leads protruding from a second one of the lateral sides of the molded body, opposite the first one of the lateral sides, wherein the molded body is free of any protrusions covering lateral faces of the second leads.

Example 10 is the power semiconductor package of one of the preceding examples, further comprising: a plating at least partially covering the first leads, wherein the lateral faces covered by the protrusions are free of the plating.

Example 11 is the power semiconductor package of one of the preceding examples, wherein the protrusions only cover those lateral faces of the first leads that are arranged perpendicular to the first and second sides of the molded body.

Example 12 is a method for fabricating power semiconductor package, the method comprising: providing a leadframe comprising a plurality of first leads, electrically connecting a power semiconductor die to the leadframe, and molding over the power semiconductor die, thereby forming a molded body, the molded body comprising a first side, an opposite second side and lateral sides connecting the first and second sides, wherein the first leads protrude from a first one of the lateral sides of the molded body, wherein the first leads comprise end faces facing away from the first one of the lateral sides of the molded body and lateral faces extending from the first one of the lateral sides to the respective end face, and wherein at least two opposite lateral faces of each of the first leads are covered by protrusions of the molded body.

Example 13 is the method of example 12, wherein the molding comprises covering preliminary end faces of the first leads with the molded body.

Example 14 is the method of example 13, further comprising: cutting through the first leads, thereby removing the preliminary end faces and fabricating the end faces of the first leads.

Example 15 is the method of example 14, wherein the cutting also comprises cutting through the protrusions, thereby forming end faces of the protrusions.

Example 16 is the method of example 15, wherein the end face of each of the first leads is coplanar with the end faces of the respective protrusions.

Example 17 is an apparatus comprising means for performing the method according to anyone of examples 12 to 16.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
a leadframe comprising a plurality of first leads;
a power semiconductor die electrically connected to the leadframe; and
a molded body encapsulating the power semiconductor die, the molded body comprising a first side, an opposite second side, and lateral sides connecting the first and second sides,
wherein the first leads protrude from a first one of the lateral sides of the molded body,
wherein the first leads comprise end faces facing away from the first one of the lateral sides of the molded body and lateral faces extending from the first one of the lateral sides to the respective end face,
wherein at least two opposite lateral faces of each of the first leads are covered by protrusions of the molded body.

2. The power semiconductor package of claim 1, wherein the end faces are cut surfaces.

3. The power semiconductor package of claim 1, wherein the protrusions comprise end faces facing away from the first one of the lateral sides, and wherein the end faces of the protrusions are cut surfaces.

4. The power semiconductor package of claim 3, wherein the end face of each first lead and the end faces of the respective protrusions are coplanar.

5. The power semiconductor package of claim 1, wherein a contour of the protrusions comprises an offset as viewed from above the first side of the molded body, such that a portion of the protrusions closer to the first one of the lateral sides has a greater thickness than a portion further away from the first one of the lateral sides.

6. The power semiconductor package of claim 5, wherein the thickness of the portion further away from the first one of the lateral sides is in a range of 0.03mm to 0.3mm.

7. The power semiconductor package of claim 1, wherein the protrusions are tapered such that a thinner side is arranged at the first side of the molded body and a thicker side is arranged at the second side of the molded body.

8. The power semiconductor package of claim 7, wherein a difference in thickness between the thinner side and the thicker side is in a range of 0.05mm to 0.2mm.

9. The power semiconductor package of claim 1, further comprising:
a plurality of second leads protruding from a second one of the lateral sides of the molded body, opposite the first one of the lateral sides,
wherein the molded body is free of any protrusions covering lateral faces of the second leads.

10. The power semiconductor package of claim 1, further comprising:
a plating at least partially covering the first leads,
wherein the lateral faces covered by the protrusions are free of the plating.

11. The power semiconductor package of claim 1, wherein the protrusions only cover those lateral faces of the first leads that are arranged perpendicular to the first and second sides of the molded body.

12. A method for fabricating a power semiconductor package, the method comprising:
providing a leadframe comprising a plurality of first leads;
electrically connecting a power semiconductor die to the leadframe; and
molding over the power semiconductor die, thereby forming a molded body, the molded body comprising a first side, an opposite second side, and lateral sides connecting the first and second sides,
wherein the first leads protrude from a first one of the lateral sides of the molded body,
wherein the first leads comprise end faces facing away from the first one of the lateral sides of the molded body and lateral faces extending from the first one of the lateral sides to the respective end face,
wherein at least two opposite lateral faces of each of the first leads are covered by protrusions of the molded body.

13. The method of claim 12, wherein the molding comprises covering preliminary end faces of the first leads with the molded body.

14. The method of claim 13, further comprising:
cutting through the first leads, thereby removing the preliminary end faces and fabricating the end faces of the first leads.

15. The method of claim 14, wherein the cutting also comprises cutting through the protrusions, thereby forming end faces of the protrusions.

16. The method of claim 15, wherein the end face of each of the first leads is coplanar with the end faces of the respective protrusions.
